(19) United States
(12) Patent Application Publication
(10) Pub. No.: US 2019/0305180 A1
(43) Pub. Date: Oct. 3, 2019

(54) LIGHT EMITTING PACKAGE

(71) Applicant: OPTIMECH CO., LTD., Hwaseong-si (KR)

(72) Inventors: Young Sik LEE, Osan-si (KR); Chung Seob KIM, Yongin-si (KR); Yu Suk HAN, Osan-si (KR)

(73) Assignee: OPTIMECH CO., LTD., Hwaseong-si (KR)

(21) Appl. No.: 16/447,077

(22) Filed: Jun. 20, 2019

Related U.S. Application Data
(63) Continuation of application No. PCT/KR2017/012110, filed on Oct. 31, 2017.

(30) Foreign Application Priority Data
Jan. 24, 2017 (KR) 10-2017-0011118

(51) Int. Cl. H01L 33/10; H01L 33/60; G02B 3/08; F21V 5/04

(52) U.S. Cl. CPC H01L 33/10; H01L 33/60; H01L 2924/12041; F21V 5/045; G02B 3/08

(57) ABSTRACT

A light emitting package is disclosed. In a light emitting package of the present invention, a lens is positioned on an upper surface of a light emitting unit, and light of the light emitting unit is thus refracted and irradiated. A light emitting package of the present invention for solving the task of the present invention includes a base, a light emitting unit coupled to the base, and a lens unit for refracting light generated by the light emitting unit, wherein the lens unit is configured by a single lens and includes a Fresnel lens portion and a convex lens portion.

### CROSS-REFERENCE TO RELATED APPLICATIONS

The present application is a continuation of International Patent Application No. PCT/KR2017/012110, filed Oct. 31, 2017, which is based upon and claims the benefit of priority to Korean Patent Application No. 10-2017-0011118, filed on Jan. 24, 2017. The disclosures of the above-listed applications are hereby incorporated by reference herein in their entirety.

### TECHNICAL FIELD

The present invention relates to a light emitting package, and more particularly, to a light emitting package in which a lens is positioned on an upper surface of a light emitting unit and light from the light emitting unit is refracted to be irradiated.

### BACKGROUND ART

Recently, the necessity of irradiating light from a light emitting package to be inclined (or tilted) to a certain degree so as to be irradiated in an electronic device equipped with the light emitting package has increased. Specifically, in a light emitting package used to assist a camera in image capturing, it is necessary to incline light from a light emitting unit so that the light from the light emitting unit may be focused on a subject. In addition, in a light emitting package for iris irradiation of an iris recognition system, it is necessary to incline light from a light emitting unit so that the light from the light emitting unit may be focused on an iris portion.

In the related art, in order to make light from the light emitting unit be inclined to be irradiated, a light emitting package is inclined to a certain degree when assembled to an electronic device. To this end, a sloped portion is provided on an assembling portion or a bottom surface of the light emitting package of the electronic device. With this method, however, an assembling process is complicated and a height of the light emitting package is increased. In addition, it is difficult to precisely maintain an inclination degree of the light emitting package during an assembling process.

Recent electronic devices tend to be light, thin, short, and small in overall size. In addition, the light emitting package used for iris irradiation in the iris recognition system is required to be considerably precise in the inclination degree of an irradiation angle of the light emitting unit. Therefore, a light emitting package capable of solving the above-mentioned problems is required.

### DISCLOSURE

### Technical Problem

An aspect of the present invention provides a light emitting package which allows light generated by a light emitting unit to be refracted at a precise angle so as to be irradiated.

Another aspect of the present invention provides a light emitting package which can be easily assembled to an electronic device and minimizes a variation in a refraction angle in accordance with assembly.

Another aspect of the present invention provides a light emitting package minimized in an overall height so as to contribute to compactness of an electronic device.

### Technical Solution

In an aspect, a light emitting package includes: a base; a light emitting unit coupled to the base; and a lens unit for refracting light generated by the light emitting unit, wherein the lens unit is configured as a single lens and includes a Fresnel lens portion and a convex lens portion.

In an embodiment of the present invention, the Fresnel lens portion may surround the convex lens portion.

In an embodiment of the present invention, the convex lens portion may be eccentrically positioned in one direction from a center of the lens unit.

In an embodiment of the present invention, the convex lens portion may have a positive refractive power.

In an embodiment of the present invention, an intermediate region may be provided between the Fresnel lens portion and the convex lens portion.

In an embodiment of the present invention, the intermediate region may be provided as a flat surface.

In an embodiment of the present invention, an absolute value of a refractive power of the intermediate region may be smaller than an absolute value of a refractive power of the convex lens portion.

In an embodiment of the present invention, the lens unit may refract light generated by the light emitting unit to be lopsided in one direction with respect to an optical axis.

In an embodiment of the present invention, when an optical axis of the lens unit is a z axis of a three-axis (x, y, and z axis) rectangular coordinate system, the Fresnel lens portion may be divided by a segment line parallel to the y axis and include a plurality of segment lens portions arranged along the x axis, and 70% or more of the plurality of segment lens portions may be formed to be inclined in one direction of the x axis.

In an embodiment of the present invention, the lens unit may refract light generated by the light emitting unit in one direction of the x axis with respect to the optical axis.

In an embodiment of the present invention, the convex lens portion may be eccentrically positioned in a direction opposite to one direction of the x axis with respect to the light emitting unit.

In an embodiment of the present invention, the light emitting package may further include a body part positioned between the base and the lens unit and surrounding the periphery of the light emitting unit.

In an embodiment of the present invention, the light emitting unit may further include a reflector formed to surround the light emitting unit.

### Advantageous Effects

The light emitting package according to an embodiment of the present invention may allow light generated by the light emitting unit to be refracted at a precise angle so as to be irradiated.

In addition, the light emitting package according to an embodiment of the present invention may be easily assembled into an electronic device and minimizes a variation in a refraction angle according to assembly.

In addition, the light emitting package according to an embodiment of the present invention may be minimized in overall height so as to contribute to compactness of an electronic device.

### DESCRIPTION OF DRAWINGS

FIG. 1 is a perspective view of a light emitting package according to an embodiment of the present invention.

FIG. 2 is an exploded perspective view of a light emitting package according to an embodiment of the present invention.

FIG. 3 is a perspective view of a lens of a light emitting package according to an embodiment of the present invention.

FIG. 4 is a cross-sectional view of a light emitting package according to an embodiment of the present invention.

### BEST MODES

Hereinafter, embodiments of the present invention will be described in detail with reference to the accompanying drawings. In describing the present invention, if it is determined that a detailed description of known functions and components associated with the present invention unnecessarily obscure the gist of the present invention, the detailed description thereof will be omitted. The terms used henceforth are used to appropriately express the embodiments of the present invention and may be altered according to a person of a related field or conventional practice. Therefore, the terms should be defined on the basis of the entire content of this specification.

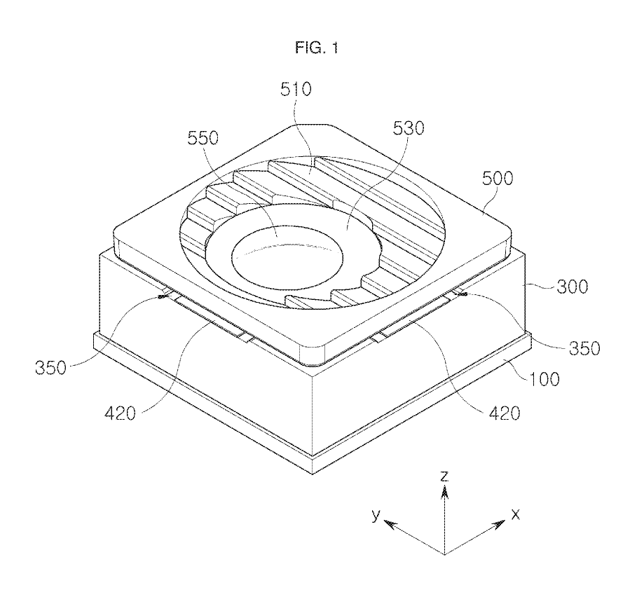

Hereinafter, a light emitting package according to an embodiment of the present invention will be described with reference to the accompanying drawings of FIGS. 1 to 4.

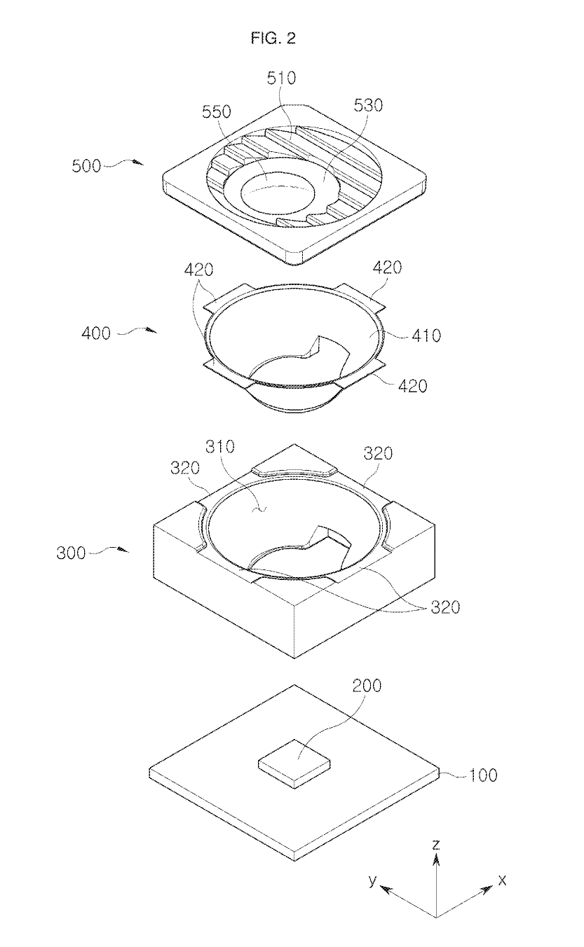

FIG. 1 is a perspective view of a light emitting package according to an embodiment of the present invention. FIG. 2 is an exploded perspective view of a light emitting package according to an embodiment of the present invention.

Referring to FIGS. 1 and 2, the light emitting package includes a base 100, a light emitting unit 200, a body part 300, a reflector 400, and a lens unit 500.

The base 100 has a flat plate shape and forms a lower portion of the light emitting package. The base 100 may be disposed parallel to an x-y plane in a three-axis coordinate system illustrated in the accompanying drawings. The base 100 may be formed of a printed circuit board (PCB). A connection terminal electrically connected to a light emitting unit 200 may be provided on an upper surface of the base 100. A power terminal (not shown) or a signal input terminal (not shown) to which power to be applied to the light emitting unit 200 is input may be provided on a lower surface of the base 100.

The light emitting unit 200 is positioned on the upper surface of the base 100. The light emitting unit 200 may be positioned at the center of the upper surface of the base 100. In addition, the body part 300 may be positioned on the upper surface of the base 100. A lower surface of the body part 300 may be coupled to and supported by the edges of the upper surface of the base 100.

The light emitting unit 200 is an electric device that emits light when power is applied. The light emitting unit 200 may be, for example, a light emitting diode (LED). The light emitting unit 200 operates upon receiving power applied from the outside and transferred through the base 100. The light emitting unit 200 emits light having a predetermined wavelength band. For example, the light emitting unit 200 may emit light having a visible light band or may emit light having an infrared light band.

The light emitting unit 200 emits light from the center thereof approximately in a direction perpendicular to the base 100. That is, the light emitting unit 200 emits light based on the z axis in the three-axis coordinate system illustrated in the accompanying drawings.

The body part 300 is positioned on the upper side of the base 100 and surrounds the periphery of the light emitting unit 200. The body part 300 includes an opening formed in an up-down direction (z-axis direction) and is coupled to the upper surface of the base 100 such that the light emitting unit 200 is positioned inside the opening. The opening may be formed to be narrow in a lower opening surface and wide in an upper opening surface. The body part 300 is formed to have light blocking properties, and the lower surface of the body part 300 and the upper surface of the base 100 may be in close contact with each other so that light emitted from the light emitting unit 200 cannot be leaked through the base 100 and the body part 300.

The reflector 400 is formed to surround the light emitting unit 200. The reflector 400 is closely attached and coupled to an inner surface of the opening of the body 300. The reflector 400 is formed to have a surface having high reflectance with respect to light emitted from the light emitting unit 200 so that light emitted from the light emitting unit 200 is reflected therefrom and irradiated upward (+z-axis direction).

The lens unit 500 is positioned above the light emitting unit 200. The lens unit 500 is coupled to cover the opening of the body part 300 from above. Therefore, light emitted from the light emitting unit 200 passes through the lens unit 500 and is irradiated to the outside of a lens package. The lens unit 500 is formed to have a refractive power, and thus, light of the light emitting unit 200 is refracted by the lens unit. The lens unit 500 will be described in more detail hereinafter.

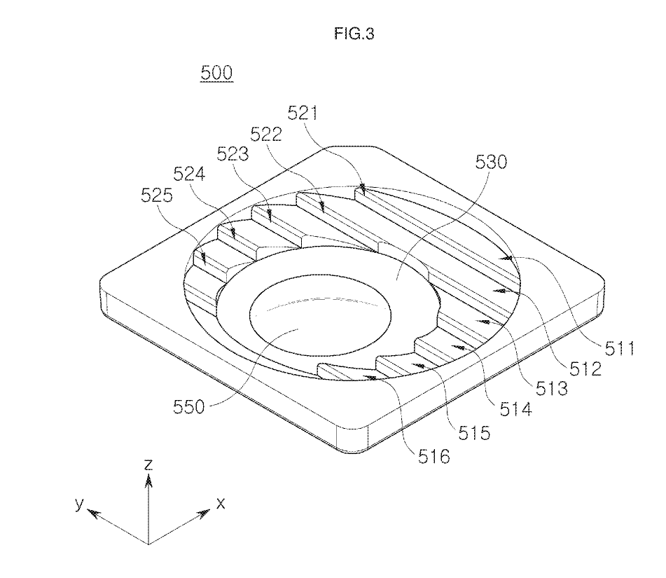

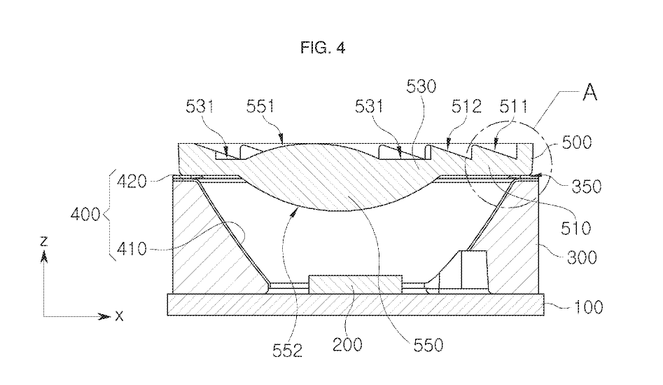

The lens unit 500 of the light emitting package of the present invention will be described in detail with reference to FIGS. 3 and 4.

FIG. 3 is a perspective view of a lens unit of a light emitting package according to an embodiment of the present invention. FIG. 4 is a cross-sectional view of a light emitting package according to an embodiment of the present invention.

The lens unit 500 is formed of a single lens. The single lens is formed to cover the opening of the body part 300 from above. The lens unit 500 is divided into a peripheral portion which corresponds to an edge portion and substantially does not have a refractive power and a central portion which corresponds to the center and substantially has a refractive power. A lower surface of the peripheral portion of the lens unit 500 may be coupled to an upper surface of the body part 300 and/or the reflector 400 to seal the opening of the body part 300.

The central portion of the lens unit 500 having a refractive power includes a Fresnel lens portion 510 and a convex lens portion 550. The Fresnel lens portion 510 is formed to surround the convex lens portion 550 when the central portion is viewed as a whole. Specifically, the convex lens portion 550 is eccentrically positioned in one direction from the center of the Fresnel lens portion 510 (that is, the convex lens portion 550 is off-centered with respect to the Fresnel lens portion 510).

The Fresnel lens portion 510 is a lens formed by dividing a spherical lens or an aspherical lens into a plurality of segment lens portions to reduce a thickness of the lens. A lens having a large aperture without increasing a thickness thereof may be formed through the Fresnel lens.

The Fresnel lens portion 510 includes a plurality of segment lens portions divided by segment lines 521 to 525. In the three-axis coordinate system illustrated in the accompanying drawings, the Fresnel lens portion 510 is divided into a plurality of segment lens portions by the segment lines 521 to 525 parallel to the y axis. The segment lens portions are arranged along the x axis in the three-axis coordinate system illustrated in the accompanying drawings. Referring to the accompanying drawings, the Fresnel lens portion 510 includes six segment lens portions divided by five segment lines 521 to 525.

The plurality of segment lens portions are formed such that all or most of the segment lens portions are oriented in the same direction. Specifically, 70% or more of the plurality of segment lens portions may be formed so as to face in the same direction. Referring to the accompanying drawings, the six segment lens portions of the Fresnel lens portion 510 are all formed to face in the same direction.

All or most of the plurality of segment lens portions may be formed such that exit surfaces 511 to 516 are oriented in the same direction. Specifically, the exit surfaces 511 to 516 of the plurality of segment lens portions may be formed to be inclined in one direction of the x axis in the three-axis coordinate system illustrated in the accompanying drawings. Referring to the accompanying drawings, the Fresnel lens portion 510 is formed such that the exit surfaces 511 to 516 of the six segment lens portions are inclined in a positive direction of the x axis.

The exit surfaces 511 to 516 of the Fresnel lens portion 510 are formed to be inclined in one direction as described above, while an incident surface of the Fresnel lens portion 510 may be formed substantially as a flat surface. As illustrated in FIG. 4, an incident surface of a lower surface of the Fresnel lens portion 510 corresponding to the exit surfaces 511 to 516 may be formed as an incident surface 552 of the convex lens portion 550, rather than as an incident surface of Fresnel lens portion 510. Therefore, the convex lens portion 550 may be formed such that an exit surface 551 of the upper surface of the convex lens portion 550 has an area smaller than that of an incident surface 552 of the lower surface of the convex lens portion 550.

The convex lens portion 550 includes the exit surface 551 of the upper surface and the incident surface 552 of the lower surface. Both the exit surface 551 and the incident surface 552 of the convex lens portion 550 may be formed in a convex shape. The convex lens portion 550 has a positive refractive power.

The convex lens portion 550 is surrounded by the Fresnel lens portion 510. The convex lens portion 550 is eccentrically formed in one direction from the center of the lens unit 500 when the position of the light emitting unit 200 corresponding to a positive direction of the z axis is the center of the lens unit 500. Specifically, the convex lens portion 550 may be eccentrically positioned in a negative direction of the x axis in the three-axis coordinate system illustrated in the accompanying drawings.

The convex lens portion 550 may be formed such that the exit surface 551 and the incident surface 552 are different from each other. As described above, the exit surface 551 of the convex lens portion 550 may have an area smaller than that of the incident surface 552. Further, the exit surface 551 of the convex lens portion 550 may be positioned to be more eccentric in one direction than the incident surface 552. Specifically, the exit surface 551 of the convex lens portion 550 may be positioned to be more eccentric in the negative direction of the x axis than the incident surface 552 in the three-axis coordinate system illustrated in the attached drawings.

An intermediate region 530 is formed between the Fresnel lens portion 510 and the convex lens portion 550. The intermediate region 530 is formed to be substantially planar without or with little refractive power. At least the intermediate region 530 is formed to have a refractive power smaller than an absolute value of the refractive power of the convex lens portion 550. In the exit surface of the lens unit 500, an exit surface 531 of the intermediate region 530, which is substantially formed as a flat surface, is clearly demarcated between the exit surfaces 511 to 516 of the Fresnel lens portion 510 and the exit surface 551 of the convex lens portion 550. Meanwhile, in the incident surface of the lens unit 500, an incident surface portion of the Fresnel lens portion 510 is formed substantially as a flat surface, and thus, the incident of the intermediate region 530 may not be present or may not be clearly demarcated.

The lens unit 500 refracts light generated by the light emitting unit 200 in one direction with respect to the optical axis. Specifically, a beam of light generated by the light emitting unit 200 has a central axis parallel to the z axis before entering the lens unit 500. After the beam of light generated by the light emitting unit 200 exits through the lens unit 500, the light has a central axis inclined from the z-axis direction. Specifically, after the beam of light generated by the light emitting unit 200 passes through the lens unit 500 illustrated in the accompanying drawings, the beam has a central axis in a direction inclined toward the positive direction of the x axis.

Due to the shape of the lens unit 500 described above, the central axis of the beam may be inclined at an appropriate angle, while the light generated by the light emitting unit 200 is maintained to concentrate at a considerable level. In addition, the thickness of the lens unit 500 may be maintained to be relatively thin, as compared with a lens which has a different optical shape and obtains the same inclination. Maintaining the lens unit 500 to be thin refers to lowering the overall height of the light emitting package, which may contribute to a reduction in size and thickness of an electronic device in which the light emitting package is installed.

It is to be understood that the present invention is not limited by the specific form of the lens unit 500 illustrated in the accompanying drawings. A person skilled in the art to which the present invention pertains may appreciate that the degree to which light of the light emitting unit 200 is refracted, or the like, is easily adjusted by regulating the positional relationship between the Fresnel lens portion 510 and the convex lens portion 550, the angle between the exit surfaces 511 to 516 and the incident surface of the Fresnel lens portion 510, the refractive power of the convex lens portion 550, or the like.

While the present invention has been shown and described in connection with the embodiments, it will be apparent to those skilled in the art that modifications and variations may be made without departing from the spirit and scope of the invention as defined by the appended claims.

| | |
|---|---|
| 100: base | 200: light emitting unit |
| 300: body part | 400: reflector |
| 500: lens unit | 510: Fresnel lens portion |
| 530: intermediate region | 550: convex lens portion |

1. A light emitting package comprising:
a base;
a light emitting unit coupled to the base; and
a lens unit for refracting light generated by the light emitting unit,
wherein the lens unit is configured as a single lens and includes a Fresnel lens portion and a convex lens portion.

2. The light emitting package of claim 1, wherein
the Fresnel lens portion surrounds the convex lens portion.

3. The light emitting package of claim 1, wherein
the convex lens portion is eccentrically positioned in one direction from a center of the lens unit.

4. The light emitting package of claim 1, wherein
the convex lens portion has a positive refractive power.

5. The light emitting package of claim 1, wherein
an intermediate region is provided between the Fresnel lens portion and the convex lens portion.

6. The light emitting package of claim 5, wherein
the intermediate region is provided as a flat surface.

7. The light emitting package of claim 5, wherein
an absolute value of a refractive power of the intermediate region is smaller than an absolute value of a refractive power of the convex lens portion.

8. The light emitting package of claim 1, wherein
the lens unit refracts light generated by the light emitting unit to be lopsided in one direction with respect to an optical axis.

9. The light emitting package of claim 1, wherein
when an optical axis of the lens unit is a z axis of a three-axis (x, y, and z axis) rectangular coordinate system,
the Fresnel lens portion is divided by a segment line parallel to the y axis and includes a plurality of segment lens portions arranged along the x axis, and
70% or more of the plurality of segment lens portions is formed to be inclined in one direction of the x axis.

10. The light emitting package of claim 9, wherein
the lens unit refracts light generated by the light emitting unit in one direction of the x axis with respect to the optical axis.

11. The light emitting package of claim 9, wherein
the convex lens portion is eccentrically positioned in a direction opposite to one direction of the x axis with respect to the light emitting unit.

12. The light emitting package of claim 1, further comprising:
a body part positioned between the base and the lens unit and surrounding the periphery of the light emitting unit.

13. The light emitting package of claim 1, wherein
the light emitting unit further includes a reflector formed to surround the light emitting unit.
